(19) United States
(12) Patent Application Publication
(10) Pub. No.: US 2005/0144764 A1
(43) Pub. Date: Jul. 7, 2005

(54) Retaining tool

(76) Inventor: Fang-Cheng Lin, Taipei (TW)

Correspondence Address: Hsu & Associates;P.O. Box 72, NANKANG, TAIPEI, TW

(21) Appl. No.: 10/747,482

(22) Filed: Dec. 25, 2003

(51) Int. Cl. A44B 21/00; H05K 7/20

(52) U.S. Cl. 24/459

(57) ABSTRACT

A retaining tool includes a press member, an engaging member and a press handle for securing a radiator to a base of a main board. The press member has an elongated elastic bent section with an end thereof having a bend and an engaging hole for engaging with an engaging jut of the base and the other end thereof being joined to the engaging member and the press handle. When the press handle at the press part thereof is pressed down to allow the press handle rotating with respect to the pivotal joint of the press handle and the engaging member, the retaining member is attached to the base by way of the fitting hole of the joining part engaging with another engaging jut of the base with the contact part thereof pressing the press part at the end fitting with the retaining member such that the elastic bent section of the press member can generate tensile deformation against the radiator to secure the radiator on the base firmly.

### BACKGROUND OF THE INVENTION

1. Field of the Invention

The present invention relates to a retaining tool, and particularly to an improved retaining tool, which is capable of being set up conveniently and performing excellent fastening job.

2. Description of Related Art

Presently, it is known that data related operation programs is getting huge and in order to be treated with the processing unit, the application programs have to be up date incessantly to reach the purpose of fast operation speed. But, a phenomenon of generating high temperature results from the processing unit treating the huge data. It is the reason why a heat dissipation device composed of a radiator and a fan has to be mounted. Cooling fins of the radiator can absorb the hot energy and the fan can speed up the air flow so that quick heat dissipation can be perform to avoid the processing unit being affected by overheat or being burned out.

However, it is one of the factor affecting the heat dissipation performance that if the radiator can be steadily attached to the processing unit. Hence, how to firmly join the radiator to the processing unit is the most important subject for treating the high heat generated by the processing unit.

The conventional retaining device for the radiator being joined to the processing unit usually has an elastic bent body with two ends thereof having a bend and an engaging hole respectively to hold an engaging piece at two lateral sides of the base. Further, the retaining device has an elongated groove for being passed through the cooling fins of the radiator such that the radiator can be fixed to the processing unit.

Although the preceding conventional retaining device allows the radiator being attached to the processing unit firmly, it is hard for the user to set up the retaining device such that other tools such as pliers, screw drivers and the like have to be used for propping up one end of elastic bent body before the retaining device can be mounted to the base and it gives the user inconvenience and puzzle.

### SUMMARY OF THE INVENTION

An object of the present invention is to provide a retaining tool, which has a feature of being assembled by the user easily.

Accordingly, the retaining tool according to the present invention includes a press member, which has an elongated elastic bent section and having a slot at one end and a bend with an engaging hole at another end thereof;
an engaging member, which has a joining part with a fitting hole at one end and has a piercing part for passing through the slot; and
a press handle with two ends, which has a contact part at one end to pivotally connect with the piercing part and has a press part at another end thereof;
whereby, when the press handle at the press part thereof is pressed down to allow the press handle rotating with respect to the pivotal joint of the press handle and the engaging member, the retaining member is attached to the base by way of the fitting hole of the joining part engaging with another engaging jut of the base with the contact part thereof pressing the press part at the end fitting with the retaining member such that the elastic bent section of the press member can generate tensile deformation against the radiator to secure the radiator on the base firmly.

### BRIEF DESCRIPTION OF THE DRAWINGS

The present invention can be more fully understood in the following description with reference to accompanying drawings, in which:

FIG. 1 is a disassembled perspective view of a retaining tool according to the present invention;

FIG. 2 is an assembled perspective view of the retaining tool shown in FIG. 1;

FIG. 3 is a perspective view illustrating operation of the retaining tool according the present invention; and

FIG. 4 is a perspective view illustrating an example using the retaining tool of the present invention.

### DETAILED DESCRIPTION OF THE PREFERRED EMBODIMENT

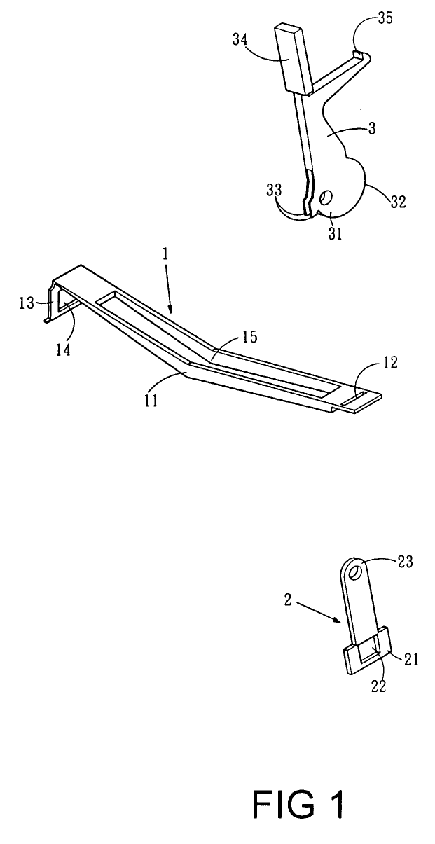

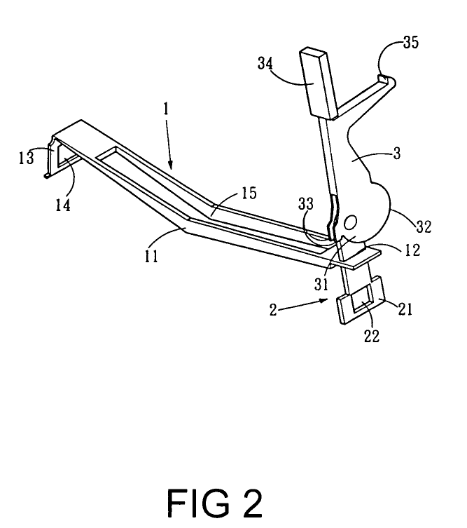

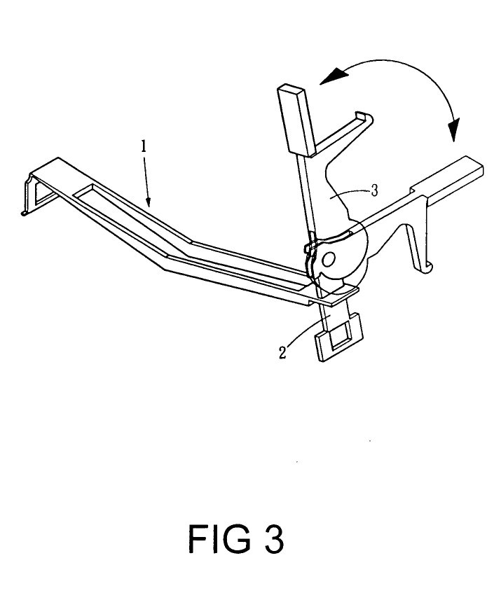

Referring to FIGS. 1, 2, 3 and 4, a retaining tool according to the present invention includes a press member 1, an engaging member 2 and a handle 3.

The press member 1 is an elongated body with elastic bent section 11. The press member 1 at an end thereof is provided with a slot 12 and at another end thereof is a downward bend end 13 with a catch hole 14. Further, the press member 1 between both ends thereof is provided with an elongated groove 15 for being passed through by cooling fins 41 of a radiator 4.

The engaging member 2 at an end thereof has a joining part 21 and the joining part 21 is provided with a fitting hole 22 for being inserted with an engaging jut 51 of the base 5. The engaging member 2 at another end thereof has a piercing part 23 corresponding to the slot 12 so that the piercing part 23 can pass through the slot 12.

The press handle 3 at an end thereof is a pivotal end 31 for connecting with the piercing part 23 and the pivotal end 31 is provided with a contact part 32 and a projection 33. The press handle 3 at another end thereof has a press part 34 and extends laterally an extension section 35.

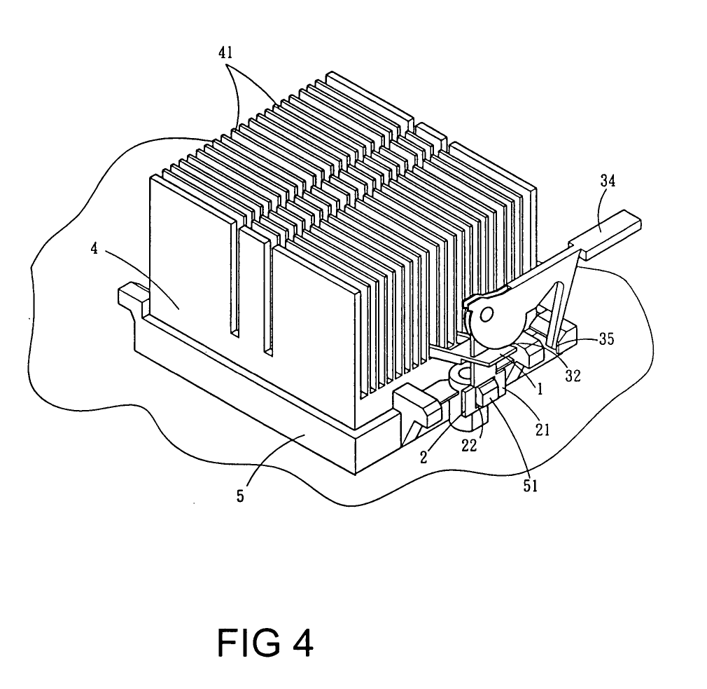

Referring to FIG. 4 again, when the retaining tool of the present invention is used, the bend end 13 of the press member 1 is attached to the base 5 in a way of an engaging jut 51 of the base 5 engaging with the catch hole 14 after a processing unit being mounted to the base 5 of the main board and the radiator 4 being disposed on the processing unit. When the press handle 3 at the press part 34 thereof is pressed down to allow the press handle 3 rotating with respect to the pivotal joint of the press handle 3 and the engaging member 2, the retaining member 2 attached to the base 5 by way of the fitting hole 22 of the joining part 21 engaging with another engaging jut 51 opposite to the first engaging jut 51 with the contact part 32 pressing the press part 1 at the end fitting with the retaining member 2 such that the elastic bent section 11 of the press member 1 can occur tensile deformation against the radiator 4 to allow the radiator being joined to the processing unit firmly.

When the retaining tool is to be detached, it is only necessary to stir the press part of the press handle in a reverse direction so as to release the press member from pressing down. Hence, the joining part of the retaining member at the fitting hole thereof detaches the corresponding engaging jut 51 to enhance features such as setting up easily and being conveniently operated.

Further, the press handle 3 at the extension section 35 thereof can provide a hook end to fasten a lateral side of the base to enhance engaging effect of the retaining tool largely.

In addition, the press handle 3 at the pivotal joint thereof can be provided with a corresponding arm instead to insert with and pivotally connect with the piercing part 23 so as to form a state of a movably pivot connection. On the contrary, the piercing part 23 can be provided with a corresponding arm instead for inserting with the pivot joint.

While the invention has been described with reference to a preferred embodiment, it is to be understood that modifications and variations may be easily made without departing from the spirit of this invention defined by the appended claim.

1. A retaining tool, comprising:
a press member with two ends, having an elongated elastic bent section and having a slot at one of the ends and a bend with an engaging hole at another one of the ends;
an engaging member with two ends, having a joining part with a fitting hole at one of the ends and having a piercing part for passing through the slot; and
a press handle with two ends, having a contact part at one of the ends to pivotally connect with the piercing part and having a press part at another one of the ends.

2. The retaining tool as defined in claim 1, wherein the press member has an elongated groove for being passed through by cooling fins of a radiator.

3. The retaining tool as defined in claim 1, wherein an extension section with an elastic hook extends laterally from the press part of the press member.
